(19) United States
(12) Patent Application Publication
(10) Pub. No.: US 2015/0136026 A1
(43) Pub. Date: May 21, 2015

(54) APPARATUS FOR PROCESSING SUBSTRATE

(71) Applicant: EUGENE TECHNOLOGY CO., LTD., Yongin-si, Gyeonggi-do (KR)

(72) Inventors: Il-Kwang Yang, Gyeonggi-do (KR); Byoung-Gyu Song, Gyeonggi-do (KR); Kyong-Hun Kim, Gyeonggi-do (KR); Yong-Ki Kim, Chungcheongnam-do (KR); Yang-Sik Shin, Gyeonggi-do (KR)

(21) Appl. No.: 14/400,807

(22) PCT Filed: Jun. 14, 2013
(86) PCT No.: PCT/KR2013/005262

§ 371 Date: Nov. 13, 2014

(30) Foreign Application Priority Data
Jun. 18, 2012 (KR) 10-2012-0065137

(51) Int. Cl. C23C 16/455; C23C 16/44; C23C 16/46

(52) U.S. Cl. CPC C23C 16/45565; C23C 16/46; C23C 16/4412
USPC 118/725

(57) ABSTRACT

Provided is a substrate processing apparatus. The substrate processing apparatus in which a process with respect to a substrate is performed includes a main chamber having a passage that is defined in one sidewall thereof to load or unload the substrate and upper and lower openings that are respectively defined in upper and lower portions thereof, a chamber cover closing the upper opening of the main chamber to provide a process space that is blocked from the outside to perform the process, a showerhead disposed in the process space, the showerhead having a plurality of spray holes that spray a process gas, a lower heating block on which the substrate is placed on an upper portion thereof, the lower heating block being fixed to the lower opening and having a lower installation space separated from the process space, and a plurality of lower heaters disposed in the lower installation space in a direction parallel to the substrate to heat the lower heating block.

### BACKGROUND OF THE INVENTION

The present invention disclosed herein relates to an apparatus for processing a substrate, and more particularly, to a substrate processing apparatus in which a heater is disposed in an installation space separated from a process space to heat a substrate.

A semiconductor device includes a plurality of layers on a silicon substrate. The layers are deposited on the substrate through a deposition process. The deposition process has several important issues. The issues are important in evaluating deposited layers and selecting a deposition method.

First, one of the important issues may be qualities of the deposited layers. This represents compositions, contamination levels, defect density, and mechanical and electrical properties of the deposited layers. The compositions of the deposited layers may be changed according to deposition conditions. This is very important for obtaining a specific composition.

Second, one of the important issues may be a uniform thickness crossing a wafer. Specifically, a thickness of a layer deposited on a pattern having a nonplanar shape in which a stepped portion is formed is very important. Whether the deposited layer has a uniform thickness may be determined through a step coverage which is defined as a value obtained by dividing a minimum thickness of a layer deposited on the stepped portion by a thickness of a layer deposited on a top surface of a pattern.

The other issue with respect to the deposition may be a filling space. This includes a gap filling in which an insulation layer including an oxide layer is filled between metal lines. The gap is provided for physically and electrically insulating the metal lines from each other. Among the above-described issues, the uniformity may be one of important issues related to the deposition process. A non-uniform layer may cause high electrical resistance on a metal line to increase possibility of mechanical damage.

Among the above-described issues, the uniformity may be one of important issues related to the deposition process. A non-uniform layer may cause high electrical resistance on a metal line to increase possibility of mechanical damage.

### SUMMARY OF THE INVENTION

The present invention provides a substrate processing apparatus that heats a substrate to perform a process.

The present invention also provides a substrate processing apparatus in which a heater is disposed in an installation space separated from a process space to control a temperature of a substrate.

Further another object of the present invention will become evident with reference to following detailed descriptions and accompanying drawings.

Embodiments of the present invention provide substrate processing apparatuses in which a process with respect to a substrate is performed, the substrate processing apparatuses including: a main chamber having a passage that is defined in one sidewall thereof to load or unload the substrate and upper and lower openings that are respectively defined in upper and lower portions thereof; a chamber cover closing the upper opening of the main chamber to provide a process space that is blocked from the outside to perform the process; a showerhead disposed in the process space, the showerhead having a plurality of spray holes that spray a process gas; a lower heating block on which the substrate is placed on an upper portion thereof, the lower heating block being fixed to the lower opening and having a lower installation space separated from the process space; and a plurality of lower heaters disposed in the lower installation space in a direction parallel to the substrate to heat the lower heating block.

In some embodiments, the substrate processing apparatuses may further include a lower exhaust tube connected to a lower exhaust hole defined in one sidewall of the lower heating block to exhaust the inside of the lower installation space.

In other embodiments, the lower heaters may be spaced apart from a bottom surface of the lower installation space.

In still other embodiments, the substrate processing apparatuses may further include a plurality of lift pins fixed to a top surface of the heating block to support a bottom surface of the substrate.

In even other embodiments, the substrate processing apparatuses may further include an exhaust port disposed in the other sidewall of the main chamber to exhaust the process gas.

In yet other embodiments, the lower heating block may have an opened lower side, and the substrate processing apparatuses may further include a lower cover closing the opened lower side of the lower heating block to isolate the lower installation space from the outside.

In other embodiments of the present invention, substrate processing apparatuses in which a process with respect to a substrate is performed, the substrate processing apparatuses include: a main chamber having a passage that is defined in one sidewall thereof to load or unload the substrate and upper and lower openings that are respectively defined in upper and lower portions thereof; an upper heating block fixed to the upper opening to close the upper opening; a lower heating block on which the substrate is placed on an upper portion thereof, the lower heating block being fixed to the lower opening to close the lower opening; a showerhead disposed in a process space defined between the upper heating block and the lower heating block, the showerhead having a plurality of spray holes that spray a process gas; a plurality of upper heaters disposed in an upper installation space that is separated from the process space and defined within the upper heating block, the plurality of upper heaters being disposed in a direction parallel to the substrate to heat the upper heating block; and a plurality of lower heaters disposed in a lower installation space that is separated from the process space and defined within the lower heating block, the plurality of lower heaters being disposed in a direction parallel to the substrate.

In some embodiments, the substrate processing apparatuses may further include: a lower exhaust tube connected to a lower exhaust hole defined in one sidewall of the lower heating block to exhaust the inside of the lower installation space; and an upper exhaust tube connected to an upper exhaust hole defined in one sidewall of the upper heating block to exhaust the inside of the upper installation space.

In other embodiments, the upper heaters and the lower heaters may be spaced apart from a ceiling surface of the upper installation space and a bottom surface of the lower installation space, respectively.

In still other embodiments, the upper and lower heating blocks may have opened upper and lower sides, respectively, and the substrate processing apparatuses may include: an upper cover closing the opened upper side of the upper heating block to isolate the upper installation space from the outside; and a lower cover closing the opened lower side of the lower heating block to isolate the lower installation space from the outside.

In even other embodiments, the showerhead may spray the process gas onto the substrate in a direction parallel to the substrate, and the spray holes may be defined at the same height.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a schematic view of a substrate processing apparatus according to an embodiment of the present invention;

FIG. 2 is a view illustrating configurations of upper heaters disposed within an upper heating block of FIG. 1;

FIG. 3 is a view illustrating configurations of lower heaters disposed within a lower heating block of FIG. 1; and

FIG. 4 is a schematic view of a substrate process apparatus according to another embodiment of the present invention.

### DETAILED DESCRIPTION OF PREFERRED EMBODIMENTS

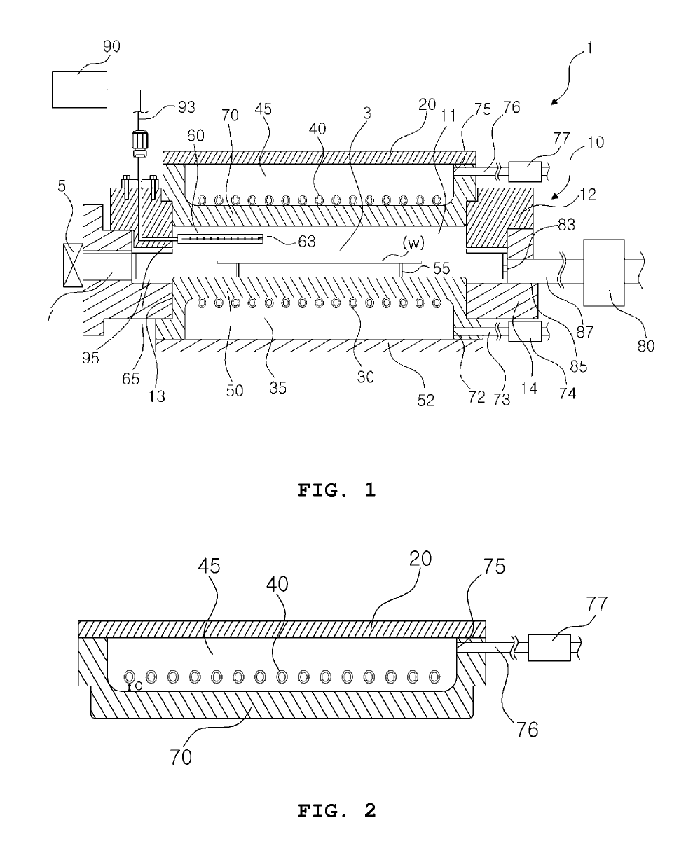

Hereinafter, exemplary embodiments of the present invention will be described in detail with reference to FIGS. 1 to 4. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the shapes of components are exaggerated for clarity of illustration.

Although a deposition process is described below as an example, the present invention is applicable to various substrate processing processes including the deposition process. Also, it is obvious to a person skilled in the art that the present invention is applicable to various objects to be processed in addition to a substrate W described in the embodiments.

FIG. 1 is a schematic view of a substrate processing apparatus according to an embodiment of the present invention. Referring to FIG. 1, a substrate process apparatus 1 includes a main chamber 10, an upper heating block 70, and a lower heating block 50. Also, processes with respect to a substrate are performed within the substrate processing apparatus 1. The main chamber 10 includes an upper chamber 12 and a lower chamber 14. The lower chamber 14 has an opened upper side. The upper chamber 12 is placed on an upper portion of the lower chamber 14 and then is coupled to the lower chamber 14. The upper chamber 12 has an upper opening 11, and the lower chamber 14 has a lower opening 13. An upper heating block 70 that will be described later is disposed on the upper opening 11 to close the upper opening 11. A lower heating block is disposed on the lower opening 13 to close the lower opening 13.

A substrate W is loaded into or unloaded from the lower chamber 14 through a passage 7 defined in a side of the lower chamber 14. A gate valve 5 is disposed on the outside of the passage 7. The passage 7 may be opened or closed by the gate valve 5. A process space 3 is defined between the upper heating block 70 and the lower heating block 50. A process with respect to the substrate is performed in a state where the substrate W is loaded into the process space 3.

The lower heating block 50 has an opened lower side. A lower cover 52 closes the opened lower side of the lower heating block 50 to isolate the inside of the lower heating block 50 from the outside. Thus, a lower installation space 35 defined inside the lower heating block 50 is separated from the process space 3 as well as is blocked from the outside. Similarly, the upper heating block 70 has an opened upper side. An upper cover 20 closes the opened upper side of the upper heating block 70 to isolate the inside of the upper heating block 70 from the outside. Thus, an upper installation space 45 defined inside the upper heating block 70 is separated from the process space 3 as well as is blocked from the outside.

Upper heaters 40 and lower heaters 30 are disposed in the upper installation space 45 and the lower installation space 35, respectively. A kanthal heater may be used as each of the upper and lower heaters 40 and 30. Kanthal may be a Fe—Cr—Al alloy, wherein iron is used as a main material. Thus, kanthal may have high heat-resistance and electric-resistance.

The upper heaters 40 and the lower heaters 30 are arranged in a direction parallel to the substrate W. The upper heaters 40 heat the upper heating block 70. That is, the upper heaters 40 indirectly heat the substrate W through the upper heating block 70. Similarly, the lower heaters 30 heat the lower heating block 50. That is, the lower heaters 30 indirectly heat the substrate W through the lower heating block 50. Thus, a heat deviation of the substrate W due to positions of the upper or lower heaters 40 or 30 may be minimized. A temperature deviation due to the positions of the upper and lower heaters 40 and 30 may be mitigated through the upper and lower heating blocks 70 and 50 to minimize the heat deviation on the substrate W. The heat deviation on the substrate W may cause process non-uniformity. As a result, a thickness deviation of a deposited thin film may occur.

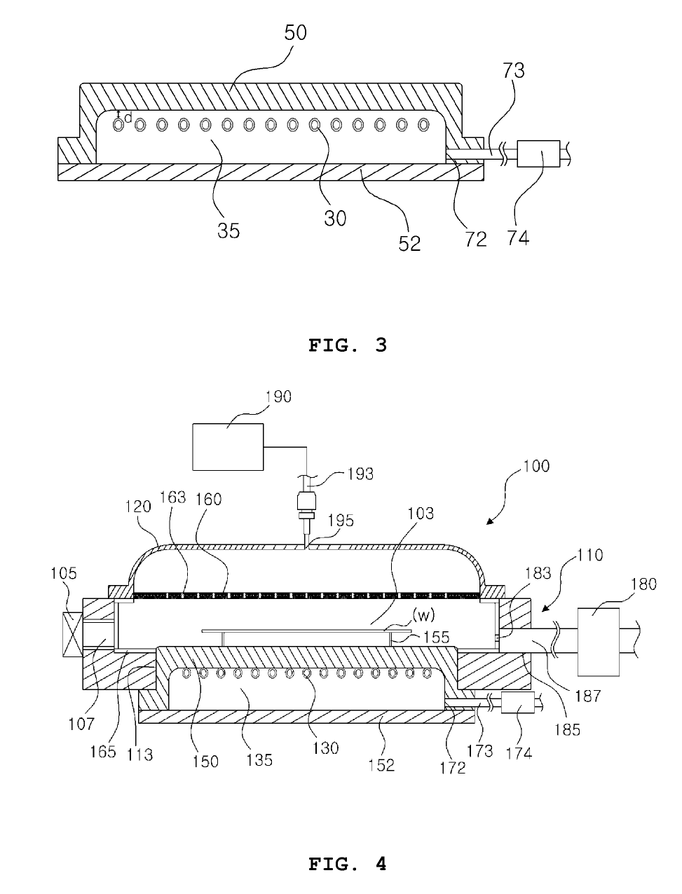

FIG. 2 is a view illustrating configurations of upper heaters disposed within an upper heating block of FIG. 1, and FIG. 3 is a view illustrating configurations of lower heaters disposed within a lower heating block of FIG. 1. Referring to FIGS. 2 and 3, the upper heaters may be spaced apart from a bottom surface of the upper heating block 70. Here, the upper heaters 40 may be fixed through a separate support unit (not shown). Similarly, the lower heaters 30 may be spaced apart from an upper surface of the lower heating block 50. Here, the lower heaters 30 may be fixed through a separate support unit (not shown). Since the upper and lower heaters 40 and 30 are spaced apart from each other (distance=d), a heat deviation on the substrate W due to the positions of the upper and lower heaters 40 and 30 may be minimized. That is, the heat deviation may be mitigated through the spaced space and minimized through the upper and lower heating blocks 70 and 50.

As described above, in a case where a heat deviation between the upper heaters 40 and the lower heaters 30 is minimized, it may be unnecessary to rotate the substrate so as to prevent the process non-uniformity from occurring. Thus, even though the lower heating block 50 on which the substrate W is placed does not rotate, a thin film may be uniformly deposited on the substrate W.

In a case where the upper and lower heaters 40 and 30 are exposed to the atmosphere, the upper and lower heaters 40 and 30 may be easily oxidized by heat, and thus be easily damaged. Thus, the upper and lower installation spaces 45 and 35 may be blocked from the outside as well as be in a vacuum state. The upper and lower heating blocks 70 and 50 have upper and lower exhaust holes 75 and 72 that are defined in sidewalls of the upper and lower heating blocks 70 and 50, respectively. Also, upper and lower exhaust tubes 76 and 73 are connected to the upper and lower exhaust holes 75 and 72, respectively. Exhaust pumps 77 and 74 are disposed in the upper and lower exhaust tubes 76 and 73, respectively. The insides of the upper and lower installation spaces 45 and 35 may be exhausted through the upper and lower exhaust tubes 76 and 73. Thus, the upper and lower installation spaces 45 and 35 may be maintained in the vacuum state.

When the upper or lower heaters 40 and 30 are maintained or repaired, a worker converts the vacuum state of the upper and lower installation spaces 45 and 35 into the atmospheric state. Then, the upper or lower cover 20 or 52 is opened so that the worker approaches the upper or lower heater 40 or 30 to easily maintain and repair the upper or lower heater 40 or 30. Here, since the upper and lower installation spaces 45 and 35 are separated from the process space 3, when the upper or lower heaters 40 or 30 are maintained and repaired, it is unnecessary to convert the vacuum state of the process space 3 into the atmospheric state. That is, the upper or lower installation space 45 or 35 may only be converted from the vacuum state into the atmospheric state to maintain and repair the upper or lower heaters 40 or 30.

Also, each of the lower and upper heating blocks 50 and 70 may be formed of a material such as high-purity quartz. Quartz has a relatively high structural strength and is chemically deactivated with respect to deposition process environments. Thus, a plurality of liners 65 for protecting an inner wall of the chamber may also be formed of a quartz material.

The substrate W moves into the substrate processing apparatus 1 through the passage 7. Then, the substrate W is placed on lift pins 55 that support the substrate W. The lift pins 55 may be fixed to an upper end of the lower heating block 50. Thus, the substrate W may be stably supported by the plurality of lift pins 55. Also, the lift pins 55 may maintain a distance between the substrate W and the lower heating block 50 at a predetermined height to minimize the heat deviation of the substrate W. Here, the distance between the substrate W and the lower heating block 50 may vary according to heights of the lift pins 55.

Each of surfaces of the lower and upper heating blocks 50 and 70 that face the substrate W has an area greater than that of the substrate W to uniformly transmit heat transmitted from the lower and upper heaters 30 and 40 into the substrate W. Also, each of the surfaces of the lower and upper heating blocks 50 and 70 facing the substrate W may have a circular disk shape corresponding to that of the substrate W.

A gas supply hole 95 is defined in a side of the main chamber 10. A supply tube 93 is disposed along the gas supply hole 95. A reaction gas is supplied from a gas storage tank 90 into the process space 3 through the supply tube 93. A showerhead 60 is connected to the supply tube 93 to spray the reaction gas onto the substrate W. The showerhead 60 is disposed between the substrate W and the upper heating block 70. Also, the showerhead 60 sprays the reaction gas onto the substrate W in a direction parallel to the substrate W. The showerhead 60 uniformly supplies the reaction gas onto the substrate W through a plurality of spray holes defined at the same height as the showerhead 60. The reaction gas may include a carrier gas such as hydrogen (H₂), nitrogen (N₂), or other inert gas. Also, the reaction gas may include precursor gases such as silane (SiH₄) or dichlorosilane (SiH₂Cl₂). Also, the reaction gas may include dopant source gases such as diborane (B₂H₆) or phosphine (PH₃).

As described above, the lower and upper heaters 30 and 40 are respectively disposed in the lower and upper installation spaces 35 and 45 to heat the substrate W through the lower and upper heating blocks 50 and 70. In the substrate processing apparatus 1, the process space 3 in which the reaction process between the reaction gas and the substrate W is performed may be minimized in volume by the lower and upper heating blocks 50 and 70. Thus, reactivity between the reaction gas and the substrate W may be improved. Also, since the process space 3 is minimized in volume, a process temperature of the substrate W may be easily controlled by the lower and upper heaters 30 and 40 respectively disposed in the lower and upper installation spaces 35 and 45.

Also, in an existing lamp heating method, a plurality of lamps are provided. Thus, if one of the plurality of lamps is broken down, or performance of each of the lamps is deteriorated, radiant heat may be locally non-uniform. However, in the case where the kanthal heaters are provided as the lower and upper heaters 30 and 40, the above-described limitation may be prevented. In addition, since kanthal heating wires of the kanthal heaters are freely modified in shape, radiant heat may be uniformly distributed and transferred when compared to the existing lamp heating method.

The lower chamber 14 includes a discharge port 85 disposed in a sidewall opposite to the gas supply hole 95. The baffle 83 is disposed on an inlet of the discharge port 85. An exhaust line 87 is connected to the discharge port 85. A non-reaction gas or byproducts within the process space 3 may move through the exhaust line 87. The non-reaction gas or byproducts may be forcibly discharged through a discharge pump 80 connected to the exhaust line 87. Also, the substrate processing apparatus 1 provides the process space 3 in which the processes are performed. Thus, while the processes are performed, the process space 3 is maintained in vacuum atmosphere having a pressure less than that of the atmosphere. In the foregoing embodiment described with reference to FIG. 1, the lower and upper heaters 30 and 40 are respectively disposed in the lower and upper installation spaces 35 and 45 so that the substrate processing apparatus is used for a high-temperature process. On the other hand, in another embodiment described with reference to FIG. 4, a substrate processing apparatus for a low-temperature process will be described.

FIG. 4 is a schematic view of a substrate processing apparatus according to another embodiment of the present invention. Referring to FIG. 4, a substrate processing apparatus 100 includes a main chamber 110 and a chamber cover 120. Also, processes with respect to a substrate W are performed within the substrate processing apparatus 100. The main chamber 110 has an opened upper side. Also, an opening 113 is defined in a lower portion of the main chamber 110. The substrate W is loaded into or unloaded from the substrate processing apparatus 100 through a passage 107 defined in a side of the main chamber 110. A gate valve 105 is disposed on the outside of the passage 107. The passage 107 may be opened or closed by the gate valve 105. The chamber cover 120 is connected to an upper end of the main chamber 110. Also, the chamber cover 120 closes the opened upper side of the main chamber 110 to provide a process space 103 in which the processes with respect to the substrate W are performed.

A heating block 150 is disposed on the opening 113 of the main chamber 110 to close the opening 113. The heating block 150 has an opened lower side. A cover 152 closes the opened lower side of the heating block 150 to isolate the inside of the heating block 150 from the outside. Thus, a installation space 135 defined inside the heating block 150 is separated from the process space 103 as well as is blocked from the outside.

Heaters 130 are disposed in the installation space 135. A kanthal heater may be used as each of the heaters 130. Kanthal may be a Fe—Cr—Al alloy, wherein iron is used as a main material. Thus, kanthal may have high heat-resistance and electric-resistance. The heaters 130 are arranged in a direction parallel to the substrate W. The heaters 130 heat the heating block 150. That is, the heaters 130 directly heat the substrate W through the heating block 150. Thus, a heat deviation of the substrate W according to positions of the heaters 130 may be minimized. A temperature deviation due to the positions of the heaters 130 may be mitigated through the heating block 130 to minimize the heat deviation on the substrate W. The heat deviation on the substrate W may cause process non-uniformity. As a result, a thickness deviation of a deposited thin film may occur.

In a case where the heaters 130 are exposed to the atmosphere, the heaters 130 may be easily oxidized by heat, and thus be easily damaged. Thus, the installation space 135 may be blocked from the outside as well as be in a vacuum state. The heating block 135 has an exhaust hole 172, and an exhaust tube 173 is connected to the exhaust hole 172. An exhaust pump 174 is connected to the exhaust tube 173 to exhaust the inside of the installation space 135 through the exhaust tube 173. Thus, the installation space 135 may be maintained in the vacuum state.

When the heaters 130 are maintained or repaired, a worker converts the vacuum state of the installation space 135 into the atmospheric state. Then, the cover 152 is opened so that the worker approaches the heater 130 to easily maintain and repair the heater 130. Here, since the installation space 135 is separated from the process space 103, when the heaters 130 are maintained and repaired, it is unnecessary to convert the vacuum state of the process space 103 into the atmospheric state. That is, the installation space 135 may only be converted from the vacuum state into the atmospheric state to maintain and repair the heaters 130.

Also, the heating block 150 may be formed of a material such as high-purity quartz. Quartz has a relatively high structural strength and is chemically deactivated with respect to deposition process environments. Thus, a plurality of liners 165 for protecting an inner wall of the chamber may also be formed of a quartz material.

The substrate W moves into the substrate processing apparatus 100 through the passage 107. Then, the substrate W is placed on lift pins 155 that support the substrate W. The lift pins 155 may be fixed to an upper end of the heating block 150. Thus, the substrate W may be stably supported by the plurality of lift pins 155. Also, the lift pins 155 may maintain a distance between the substrate W and the heating block 150 at a predetermined height to minimize the heat deviation of the substrate W. Here, the distance between the substrate W and the heating block 150 may vary according to heights of the lift pins 155.

Referring to FIG. 4, a gas supply hole 195 is defined in an upper portion of the chamber cover 120. A gas supply tube 193 may be connected to the gas supply hole 195. The gas supply tube 193 is connected to a gas storage tank 190 to supply reaction gases from the gas storage tank 190 into the process space 103 of the substrate processing apparatus 100. The gas supply tube 193 is connected to a showerhead 160. The showerhead 160 has a plurality of spray holes 163 to diffuse the reaction gases supplied from the gas supply tube 193, thereby spraying the diffused reaction gas onto the substrate W. The showerhead 160 may be disposed at a preset position above the substrate W.

The main chamber 110 includes a discharge port 185 disposed in a sidewall thereof. The baffle 183 is disposed on an inlet of the discharge port 185. An exhaust line 187 is connected to the discharge port 185. A non-reaction gas or byproducts within the process space 103 may move through the exhaust line 187. The non-reaction gas or byproducts may be forcibly discharged through a discharge pump 180 connected to the exhaust line 187. Also, the substrate processing apparatus 100 provides the process space 3 in which the processes are performed. Thus, while the processes are performed, the process space 103 is maintained in vacuum atmosphere having a pressure less than that of the atmosphere.

Also, in an existing lamp heating method, a plurality of lamps are provided. Thus, if one of the plurality of lamps is broken down, or performance of each of the lamps is deteriorated, radiant heat may be locally non-uniform. However, in the case where the kanthal heaters are provided as the heaters 130, the above-described limitation may be prevented. In addition, since kanthal heating wires of the kanthal heaters are freely modified in shape, radiant heat may be uniformly distributed and transferred when compared to the existing lamp heating method.

In a case where the heaters 130 disposed in the installation space 135 are exposed to the atmosphere, the heaters 130 may be easily oxidized by heat, and thus be easily damaged. Thus, the installation space 135 may be blocked from the outside as well as be in a vacuum state. The heating block 135 has the exhaust hole 172 defined in a sidewall thereof, and the exhaust tube 173 is connected to the exhaust hole 172. An exhaust pump 174 is connected to the exhaust tube 173 to exhaust the inside of the installation space 135 through the exhaust tube 173. Thus, the installation space 135 may be maintained in the vacuum state.

According to the embodiment of the present invention, a temperature of the substrate may be controlled by using the heaters. Also, since the heaters are disposed in the installation space separated from the process space, the heaters may be easily maintained and repaired. Also, when the substrate is heated, the temperature deviation of the substrate may be minimized.

Although the present invention is described in detail with reference to the exemplary embodiments, the invention may be embodied in many different forms. Thus, technical idea and scope of claims set forth below are not limited to the preferred embodiments.

What is claimed is:

1. A substrate processing apparatus in which a process with respect to a substrate is performed, the substrate processing apparatus comprising:
a main chamber having a passage that is defined in one sidewall thereof to load or unload the substrate and upper and lower openings that are respectively defined in upper and lower portions thereof;
a chamber cover closing the upper opening of the main chamber to provide a process space that is blocked from the outside to perform the process;
a showerhead disposed in the process space, the showerhead having a plurality of spray holes that spray a process gas;
a lower heating block on which the substrate is placed on an upper portion thereof, the lower heating block being fixed to the lower opening and having a lower installation space separated from the process space; and
a plurality of lower heaters disposed in the lower installation space in a direction parallel to the substrate to heat the lower heating block.

2. The substrate processing apparatus of claim 1, further comprising a lower exhaust tube connected to a lower exhaust hole defined in one sidewall of the lower heating block to exhaust the inside of the lower installation space.

3. The substrate processing apparatus of claim 1, wherein the lower heaters are spaced apart from a bottom surface of the lower installation space.

4. The substrate processing apparatus of claim 1, further comprising a plurality of lift pins fixed to a top surface of the heating block to support a bottom surface of the substrate.

5. The substrate processing apparatus of claim 1, further comprising an exhaust port disposed in the other sidewall of the main chamber to exhaust the process gas.

6. The substrate processing apparatus of claim 1, wherein the lower heating block has an opened lower side, and
the substrate processing apparatus further comprises a lower cover closing the opened lower side of the lower heating block to isolate the lower installation space from the outside.

7. A substrate processing apparatus in which a process with respect to a substrate is performed, the substrate processing apparatus comprising:
a main chamber having a passage that is defined in one sidewall thereof to load or unload the substrate and upper and lower openings that are respectively defined in upper and lower portions thereof;
an upper heating block fixed to the upper opening to close the upper opening;
a lower heating block on which the substrate is placed on an upper portion thereof, the lower heating block being fixed to the lower opening to close the lower opening;
a showerhead disposed in a process space defined between the upper heating block and the lower heating block, the showerhead having a plurality of spray holes that spray a process gas;
a plurality of upper heaters disposed in an upper installation space that is separated from the process space and defined within the upper heating block, the plurality of upper heaters being disposed in a direction parallel to the substrate to heat the upper heating block; and
a plurality of lower heaters disposed in a lower installation space that is separated from the process space and defined within the lower heating block, the plurality of lower heaters being disposed in a direction parallel to the substrate.

8. The substrate processing apparatus of claim 7, further comprising:
a lower exhaust tube connected to a lower exhaust hole defined in one sidewall of the lower heating block to exhaust the inside of the lower installation space; and
an upper exhaust tube connected to an upper exhaust hole defined in one sidewall of the upper heating block to exhaust the inside of the upper installation space.

9. The substrate processing apparatus of claim 7, wherein the upper heaters and the lower heaters are spaced apart from a ceiling surface of the upper installation space and a bottom surface of the lower installation space, respectively.

10. The substrate processing apparatus of claim 7, wherein the upper and lower heating blocks have opened upper and lower sides, respectively, and
the substrate processing apparatus comprises:
an upper cover closing the opened upper side of the upper heating block to isolate the upper installation space from the outside; and
a lower cover closing the opened lower side of the lower heating block to isolate the lower installation space from the outside.

11. The substrate processing apparatus of claim 1, wherein the showerhead sprays the process gas onto the substrate in a direction parallel to the substrate, and
the spray holes are defined at the same height.
